(19) United States
(12) Patent Application Publication
(10) Pub. No.: US 2020/0227312 A1
(43) Pub. Date: Jul. 16, 2020

(54) SEMICONDUCTOR DEVICES INCLUDING ADHESION PROMOTING STRUCTURES AND METHODS FOR MANUFACTURING THEREOF

(71) Applicant: Infineon Technologies AG, Neubiberg (DE)

(72) Inventors: Irmgard Escher-Poeppel, Duggendorf (DE); Thorsten Scharf, Regensburg (DE); Catharina Wille, Regensburg (DE)

(73) Assignee: Infineon Technologies AG, Neubiberg (DE)

(21) Appl. No.: 16/690,984

(22) Filed: Nov. 21, 2019

(30) Foreign Application Priority Data
Jan. 15, 2019 (DE) 10 2019 100 896.4

(51) Int. Cl. H01L 21/768; H01L 23/16; H01L 23/31; H01L 23/48

(52) U.S. Cl. CPC H01L 21/76814; H01L 23/16; H01L 21/76877; H01L 23/481; H01L 23/3107

(57) ABSTRACT

A semiconductor device and method is disclosed. In one example, the method includes forming a recess in an electrically insulating encapsulation material, wherein the encapsulation material at least partly encapsulates a semiconductor chip. The method further includes forming an adhesion promoting structure in the recess. The method further includes spraying an electrically conductive material into the recess, wherein the adhesion promoting structure is configured to provide an adhesion between the sprayed electrically conductive material and the encapsulation material.

### CROSS-REFERENCE TO RELATED APPLICATION

This Utility Patent Application claims priority to German Patent Application No. 10 2019 100 896.4, filed Jan. 15, 2019, which is incorporated herein by reference.

### TECHNICAL FIELD

The present disclosure generally relates to semiconductor technology. In particular, the present disclosure relates to semiconductor devices including adhesion promoting structures and methods for manufacturing thereof.

### BACKGROUND

The size of semiconductor devices is continuously reduced in order to achieve competitive cost and performance targets. There may be specific restrictions for power devices, as high currents have to be processed at smaller and smaller dimensions. For example, a drain electrode of a power chip backside may be soldered to a leadframe while a source electrode of a power chip frontside may be soldered to a metal clip. Such arrangement may result in long conducting paths and high electrical resistances as well as an increased effort to cool the device. Manufacturers of semiconductor devices are constantly striving to improve their products and methods for manufacturing thereof. It may thus be desirable to develop methods for manufacturing semiconductor devices that provide an improved and cost-efficient production of the devices and that may be particularly suited for the production of power devices.

### SUMMARY

An aspect of the present disclosure relates to a method. The method comprises forming a recess in an electrically insulating encapsulation material, wherein the encapsulation material at least partly encapsulates a semiconductor chip. The method further comprises forming an adhesion promoting structure in the recess. The method further comprises spraying an electrically conductive material into the recess, wherein the adhesion promoting structure is configured to provide an adhesion between the sprayed electrically conductive material and the encapsulation material.

A further aspect of the present disclosure relates to a semiconductor device. The semiconductor device comprises a semiconductor chip. The semiconductor device further comprises an electrically insulating encapsulation material at least partly encapsulating the semiconductor chip. The semiconductor device further comprises a recess arranged in the encapsulation material. The semiconductor device further comprises a sprayed electrically conductive material arranged in the recess. The method further comprises an adhesion promoting structure arranged in the recess and configured to provide an adhesion between the sprayed electrically conductive material and the encapsulation material.

### BRIEF DESCRIPTION OF THE DRAWINGS

The accompanying drawings are included to provide a further understanding of aspects and are incorporated in and constitute a part of this description. The drawings illustrate aspects and together with the description serve to explain principles of aspects. Other aspects and many of the intended advantages of aspects will be readily appreciated as they become better understood by reference to the following detailed description. The elements of the drawings are not necessarily to scale relative to each other. Like reference signs may designate corresponding similar parts.

FIG. 1 includes FIGS. 1A to 1C schematically illustrating a cross-sectional side view of a method for manufacturing a semiconductor device 100 in accordance with the disclosure.

FIG. 2 schematically illustrates a cross-sectional side view of a semiconductor device 200 in accordance with the disclosure.

FIG. 3 schematically illustrates a cross-sectional side view of an adhesion promoting structure of a semiconductor device 300 in accordance with the disclosure.

FIG. 4 schematically illustrates a cross-sectional side view of an adhesion promoting structure of a semiconductor device 400 in accordance with the disclosure.

FIG. 5 schematically illustrates a cross-sectional side view of an adhesion promoting structure of a semiconductor device 500 in accordance with the disclosure.

FIG. 6 includes FIGS. 6A to 6C schematically illustrating a cross-sectional side view of a method for manufacturing a semiconductor device 600 in accordance with the disclosure.

FIG. 7 schematically illustrates a cross-sectional side view of a semiconductor device 700 in accordance with the disclosure.

FIG. 8 schematically illustrates a cross-sectional side view of a semiconductor device 800 in accordance with the disclosure.

FIG. 9 schematically illustrates a cross-sectional side view of a semiconductor device 900 in accordance with the disclosure.

FIG. 10 illustrates a flowchart of a method for manufacturing a semiconductor device in accordance with the disclosure.

FIG. 11 schematically illustrates an arrangement 1100 for applying a cold gas spraying technique.

FIG. 12 schematically illustrates a supersonic nozzle 1200 providing a gas stream including particles to be deposited on a target.

FIG. 13 is a stress-temperature diagram illustrating a temperature-dependency of stress that may occur in cooper layers manufactured by different deposition methods.

### DESCRIPTION OF EMBODIMENTS

In the following detailed description, reference is made to the accompanying drawings, in which are shown by way of illustration specific aspects in which the disclosure may be practiced. In this regard, directional terminology, such as “top”, “bottom”, “front”, “back”, etc. may be used with reference to the orientation of the figures being described. Since components of described devices may be positioned in a number of different orientations, the directional terminology may be used for purposes of illustration and is in no way limiting. Other aspects may be utilized and structural or logical changes may be made without departing from the concept of the present disclosure. Hence, the following detailed description is not to be taken in a limiting sense, and the concept of the present disclosure is defined by the appended claims.

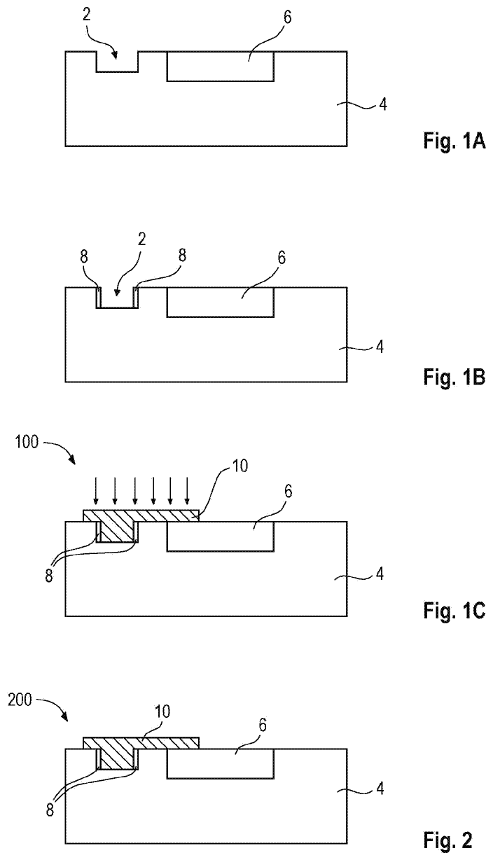

FIG. 1 includes FIGS. 1A to 1C schematically illustrating a cross-sectional side view of a method for manufacturing a semiconductor device 100 in accordance with the disclosure. The method of FIG. 1 is illustrated in a general manner in order to qualitatively specify aspects of the disclosure. The method may include further aspects which are not illustrated for the sake of simplicity. For example, the method may be extended by any of the aspects described in connection with other methods and devices in accordance with the disclosure.

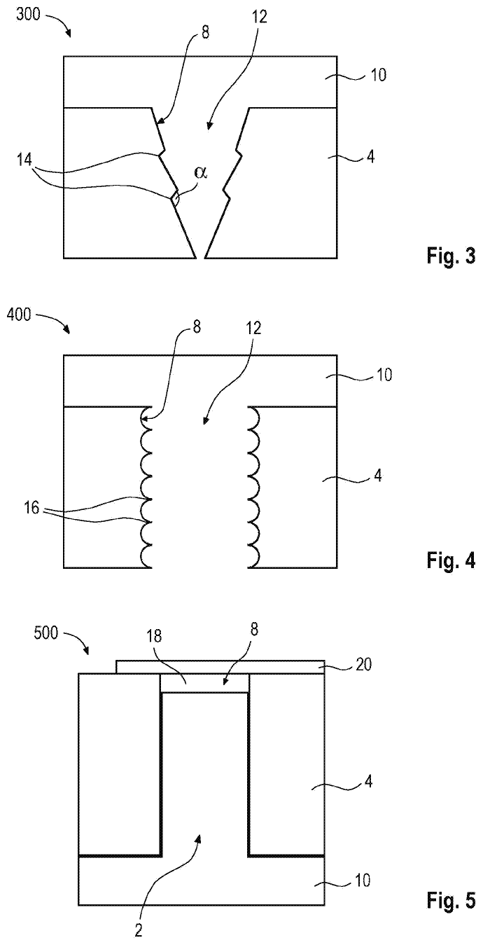

In FIG. 1A, a recess 2 is formed in an electrically insulating encapsulation material 4, wherein the encapsulation material 4 at least partly encapsulates a semiconductor chip 6. In the example of FIG. 1A, the encapsulation material 4 may cover the bottom surface and the side surfaces of the semiconductor chip 6. In further examples, the encapsulation material 4 may only cover the side surfaces of the semiconductor chip 6 or may additionally cover the upper surface of the semiconductor chip 6. In the example of FIG. 1A, the recess 2 may have an exemplary rectangular cross-section. In further examples, the shape of the recess 2 may be different (see e.g. FIGS. 3 and 4).

In FIG. 1B, an adhesion promoting structure 8 is formed in the recess 2. In the example of FIG. 1B, the adhesion promoting structure 8 may be arranged on sidewalls of the recess 2. In further examples, the adhesion promoting structure 8 may additionally or exclusively cover the bottom of the recess 2. The adhesion promoting structure 8 may correspond to a specific surface structure of one or more surfaces of the recess 2 (see e.g. FIGS. 3 and 4). Alternatively or additionally, the adhesion promoting structure 8 may correspond to a material structure, such as e.g. an adhesion promoting material layer (see e.g. FIG. 5).

In FIG. 1C, an electrically conductive material 10 is sprayed into the recess 2 (see arrows), wherein the adhesion promoting structure 8 is configured to provide an adhesion between the sprayed electrically conductive material 10 and the encapsulation material 4. The adhesion promoting structure 8 may thus have an adhesive function similar to e.g. a dowel or an adhesive material.

The example of FIG. 1 illustrates only one semiconductor chip 6 embedded in the encapsulation material 4. Note that the method of FIG. 1 may be performed in parallel with respect to multiple of such arrangements. For example, the acts of a method in accordance with the disclosure may be performed on wafer level. In particular, the manufactured semiconductor devices may be part of a reconfigured wafer and may be manufactured based on an eWLB (embedded wafer level ball grid array) technique. By applying an additional dicing act, the reconfigured wafer may be singulated in multiple semiconductor devices in accordance with the disclosure.

The semiconductor chip 6 may include integrated circuits, passive electronic components, active electronic components, etc. In general, the integrated circuits may be designed as logic integrated circuits, analog integrated circuits, mixed signal integrated circuits, power integrated circuits, etc. In one example, the semiconductor chip 6 may be manufactured from an elemental semiconductor material, for example Si, etc. In a further example, the semiconductor chip 6 may be manufactured from a compound semiconductor material, for example GaN, SiC, SiGe, GaAs, etc. In particular, the semiconductor chip 6 may include one or more power semiconductors. Power semiconductor chips may be configured as diodes, power MOSFETs (Metal Oxide Semiconductor Field Effect Transistors), IGBTs (Insulated Gate Bipolar Transistors), JFETs (Junction Gate Field Effect Transistors), HEMTs (High Electron Mobility Transistors), super junction devices, power bipolar transistors, etc. Power semiconductor chips may be of vertical or lateral type.

The encapsulation material 4 may include or may be made of at least one of an epoxy, a filled epoxy, a glass fiber filled epoxy, a glass fiber filled polymer, an imide, a filled or non-filled thermoplastic polymer material, a filled or non-filled duroplastic polymer material, a filled or non-filled polymer blend, a thermosetting material, a thermoplast material, a mold compound, a laminate material, etc. Various techniques may be used to manufacture the encapsulation material 4, for example at least one of compression molding, injection molding, powder molding, liquid molding, lamination, etc. A “filled” encapsulation material may include at least one of filler particles and filler fibers as discussed below.

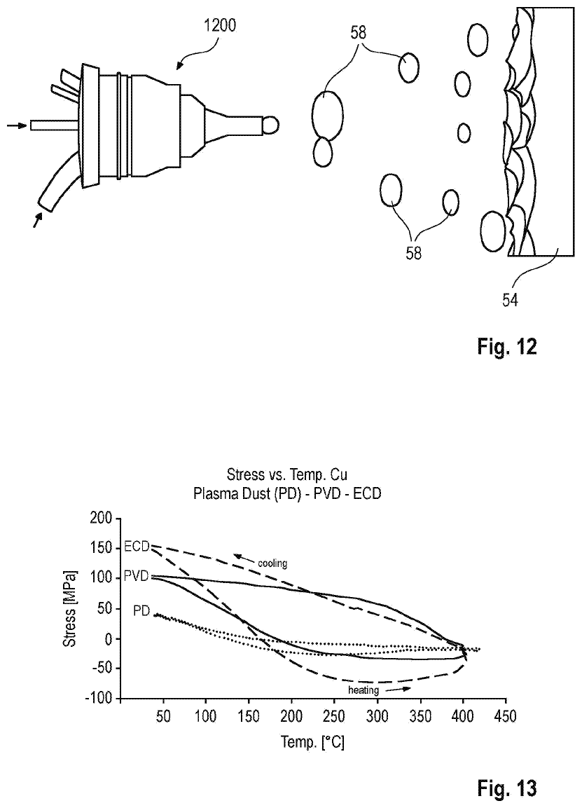

According to an embodiment spraying the electrically conductive material 10 may include at least one of cold gas spraying and plasma dust spraying the electrically conductive material 10. Cold gas spraying and plasma dust spraying may correspond to coating deposition methods in which solid (powder) particles of the electrically conductive material 10 may be accelerated. The accelerated particles may hit surfaces of the recess 2, thereby undergoing plastic deformation and adhering to the target surfaces. An exemplary arrangement for applying a cold gas spraying technique and its operation is discussed in connection with FIGS. 11 and 12.

According to an embodiment the sprayed material 10 may include at least one of copper, aluminum, iron, nickel, alloys thereof, bronze, brass. More general, the sprayed material 10 may include or may be made of a metal or metal alloy providing desired material properties. In particular, the sprayed material 10 may be configured to provide at least one of an improved electrical and thermal conductivity. In addition, the sprayed material 10 may be configured to provide specific magnetic properties, such as e.g. a ferromagnetic material.

According to an embodiment forming the recess 2 may include applying at least one of an etching process and a laser process to the encapsulation material 4. In addition, forming the adhesion promoting structure 8 may include roughening a sidewall of the recess 2 by the at least one of the etching process and the laser process. The etching process may be based on a wet etching technique or a dry etching technique. A dry etching process may particularly be based on a plasma etching technique employing a plasma, such as e.g. Reactive Ion Etching, Deep Reactive Ion Etching, Ion Beam Etching, etc. The laser process may e.g. be based on a laser drilling technique. After performing the etching process and/or the laser process, one or more surfaces of the recess 2 may have obtained a roughened surface structure.

According to an embodiment roughening the sidewall may include forming at least one of scallops and undercuts on the sidewall. An example of a roughened sidewall having a scalloped (or undulated) structure is shown and discussed in connection with FIG. 4. A side wall including scallops (or undulations) may e.g. be obtained by applying a laser drilling process to a substrate including filler fibers, in particular glass fibers. An example for a roughened sidewall including undercuts is shown and discussed in connection with FIG. 3. A sidewall including undercuts may e.g. be obtained by applying an etching process to a mold compound including silicon oxide filler particles.

According to an embodiment the encapsulation material 4 may include at least one of filler particles and filler fibers. In addition, roughening the sidewall may include breaking the at least one of the filler particles and the filler fibers out of the encapsulation material 4 during the at least one of the etching process and the laser process. The fillers may alter and adjust physical properties of the encapsulation material 4 locally or over a larger scale. In one example, the fillers may include at least one of silicon nitride, silicon oxide, glass, carbon, polyimides, polyesters, polyamides, etc. Such fillers may increase the mechanical hardness of the filled encapsulation material 4. In a further example, the fillers may include at least one of boron nitride, aluminum nitride, metals, etc. Such fillers may increase the thermal conductivity of the filled encapsulation material. In yet one further example, the fillers may include a metal and/or a metal alloy, in particular at least one of Cu, Ni, Fe, Ag, Al, alloys of said metals, etc. Such fillers may increase the electrical conductivity and the electromagnetic shielding capability of the filled encapsulation material 4.

The fillers may be substantially ball-shaped filler particles which may have a diameter in a range from about 10 micrometer to about 100 micrometer. Alternatively, the fillers may have the form of fibers, such as e.g. glass fibers. In particular, fiber fillers may be added to provide strength or mechanical hardness to the encapsulation material 4. Fiber fillers may particularly include or may be made of glass, carbon, polyimides, polyesters, polyamides, etc. When applying an etching process or a laser process to the encapsulation material 4, parts of the filler particles or filler fibers may be broken out of the basic material embedding the fillers. Breaking out the fillers may result in roughened surfaces of the recess 2 as e.g. shown and discussed in connection with FIGS. 3 and 4.

According to an embodiment forming the recess 2 may include forming a via hole, wherein the via hole may extend through the encapsulation material 4 from a first surface of the encapsulation material 4 to a second surface of the encapsulation material 4. Referring back to FIG. 1A, a depth of the recess 2 may be further increased by applying at least one of an etching process and a laser process until a via hole is formed.

According to an embodiment spraying the electrically conductive material 10 may include forming an electrical via connection through the encapsulation material 4, wherein the electrical via connection may be electrically coupled to the semiconductor chip 6. For example, the recess 2 may be a via hole extending from the upper surface to the lower surface of the encapsulation material 4. The via hole filled with the electrically conductive material 10 may form a through encapsulation via (TEV) configured to make an electrical contact arranged on the upper surface of the semiconductor chip 6 accessible on the bottom surface of the encapsulation material 4.

According to an embodiment forming the adhesion promoting structure 8 may include forming an adhesion promoting layer in the recess. An exemplary adhesion promoting layer formed at the bottom of a recess is shown and discussed in connection with FIG. 5.

According to an embodiment forming the adhesion promoting layer may include forming the recess 2 in a first surface of the encapsulation material 4 until an electrically conductive structure arranged on a second surface of the encapsulation material 4 may be exposed from the encapsulation material 4 at the bottom of the recess. In particular, the electrically conductive structure may be a conductor track. An adhesion promoting layer including a conductor track on the bottom of the recess 2 is shown and discussed in connection with FIG. 5.

According to an embodiment, after spraying the electrically conductive material 10, sidewalls of the recess 2 may be uncovered by the adhesion promoting layer. For example, the adhesion promoting structure 8 may be exclusively formed by a conductor track forming a bottom of the recess 2. In this case, the adhesion promoting structure 8 may not necessarily cover the sidewalls of the recess 2.

According to an embodiment the adhesion promoting layer may include a soft metal, in particular aluminum. A hardness of a material may be measured in units of Mohs. For example, aluminum may have a Mohs hardness value of about 2.75, copper may have a Mohs hardness value of about 3.0, and gold may have a Mohs hardness value of about 2.5. The hardness of the soft metal included in or forming the adhesion promoting layer may have a Mohs hardness value of smaller than about 3.1, more particular smaller than about 3.0, more particular smaller than about 2.8, more particular smaller than about 2.6, and even more particular smaller than about 2.5. The soft metal may be configured to get deformed when particles of the electrically conductive material 10 are sprayed on it. The deformation of the soft metal may contribute to an adhesion between the deposited particles of the sprayed material 10 and the adhesion promoting layer.

According to an embodiment the method of FIG. 1 may further include spraying the electrically conductive material 10 over at least one of a surface of the encapsulation material 4 and a surface of the semiconductor chip 6. In this case, the electrically conductive material 10 may be not exclusively sprayed into the recess 2, but may also cover a bottom or top surface of the semiconductor device that is to be manufactured. In one example, the additionally deposited material may form one or more contact pads of the device. In a further example, the additionally deposited material may form a heatsink. In yet one further example, the additionally deposited material may form one or more conductor tracks of the device.

FIG. 2 schematically illustrates a cross-sectional side view of a semiconductor device 200 in accordance with the disclosure. The semiconductor device 200 is illustrated in a general manner in order to qualitatively specify aspects of the disclosure. The semiconductor device 200 may include further components which are not illustrated for the sake of simplicity. For example, the semiconductor device 200 may be extended by any of the aspects described in connection with other devices and methods in accordance with the disclosure.

The semiconductor device 200 includes a semiconductor chip 6. The semiconductor device 200 further includes an electrically insulating encapsulation material 4 at least partly encapsulating the semiconductor chip 6. The semiconductor device 200 further includes a recess 2 arranged in the encapsulation material 4. The semiconductor device 200 further includes a sprayed electrically conductive material 10 arranged in the recess 2. The semiconductor device 200 further includes an adhesion promoting structure 8 arranged in the recess 2 and configured to provide an adhesion between the sprayed electrically conductive material 10 and the encapsulation material 4. For example, the semiconductor device 200 may be manufactured according to the method of FIG. 1.

According to an embodiment the adhesion promoting structure 8 may include at least one of scallops and undercuts formed on a sidewall of the recess 2, wherein the sprayed material 10 and the sidewall may be interlocked by the at least one of the scallops and the undercuts. An example for an interlock between the sprayed material 10 and a sidewall by means of undercuts is shown and discussed in connection with FIG. 3. An example for an interlock between the sprayed material 10 and a sidewall by means of scallops is shown and discussed in connection with FIG. 4.

According to an embodiment the recess 2 may be arranged in a first surface of the encapsulation material 4. In addition, an electrically conductive structure may be arranged on a second surface of the encapsulation material 4. Further, the electrically conductive structure may form a bottom of the recess 2. In addition, the adhesion promoting structure 8 may include the electrically conductive structure. An adhesion promoting layer including an electrically conductive structure in form of a conductor track on the bottom of a recess is shown and discussed in connection FIG. 5.

According to an embodiment a porosity of the sprayed material 10 may lie in a range from 10% to 50%. The porosity of the sprayed material 10 may be controlled by process and hardware parameters. The porosity may be dimensionless and may correspond to the ratio of the void volume to the total volume of the porous material or of the body formed from the porous material. In this connection, it is to be noted that a metal or metal alloy material manufactured by cold gas spraying may be distinguished from e.g. a bulk material layer of the same material.

According to an embodiment the encapsulation material 4 may include at least one of filler particles and filler fibers as discussed above.

According to an embodiment the sprayed material 10 may form an electrical via connection between a first surface and a second surface of the encapsulation material 4. Referring back to FIG. 1A, a via hole filled with a sprayed electrically conductive material may form a Through Encapsulation Via (TEV) providing an electrical connection between the upper and bottom main surfaces of the encapsulation material 4.

According to an embodiment the sprayed material 10 may be further arranged over at least one of a surface of the encapsulation material 4 and a surface of the semiconductor chip 6. In addition, the sprayed material 10 may form at least one of a conductor track and a heatsink.

FIG. 3 schematically illustrates a cross-sectional side view of an adhesion promoting structure of a semiconductor device 300 in accordance with the disclosure. FIG. 3 may be seen as a more detailed illustration of corresponding components of FIGS. 1 and 2. The semiconductor device 300 may inter alia include an encapsulation material 4 and a through-hole 12 extending from the upper surface of the encapsulation material 4 to the bottom surface of the encapsulation material 4. The through-hole 12 may correspond to the recess 2 of FIG. 1, but may fully extend through the encapsulation material 4. In the example of FIG. 3, the sidewalls of the through-hole 12 may be substantially V-shaped. In further examples, the sidewalls may be substantially parallel to each other. An electrically conductive material 10 may be sprayed into the through-hole 12 and over the upper surface of the encapsulation material 4 by applying a spraying technique. For example, the electrically conductive material 10 may provide an electrical connection through the encapsulation material 4, but may also provide a heat dissipation through the encapsulation material 4 supporting a cooling of the semiconductor device 300.

In the example of FIG. 3, an adhesion promoting structure 8 may be provided by a surface structure of the sidewalls of the through-hole 12. The sidewalls of the through-hole 12 may include an arbitrary number of undercuts 14. For example, a sidewall including undercuts may be obtained by applying an etching process to an encapsulation material in form of a mold compound including silicon oxide filler particles. In one example, an angle α of an undercut 14 may be greater than or equal to 90°. In a further example, the angle α may be smaller than or equal to 90°. An adhesion between the electrically conductive material 10 and the encapsulation material 4 may be provided by an interlock between the electrically conductive material 10 and the undercuts 14 of the roughened sidewalls of the through-hole 12.

FIG. 4 schematically illustrates a cross-sectional side view of an adhesion promoting structure of a semiconductor device 400 in accordance with the disclosure. FIG. 4 may be seen as a more detailed illustration of corresponding components of FIGS. 1 and 2. The components of FIG. 4 may at least partly be similar to the components of FIG. 3. In contrast to FIG. 3, the sidewalls of the through-hole 12 may include an arbitrary number of scallops (or undulations) 16 and may thus have a scalloped (or undulated) structure. For example, a side wall having a scalloped structure may be obtained by applying laser drilling to a substrate including glass fibers or glass particles. Similar to FIG. 3, an adhesion between the electrically conductive material 10 and the encapsulation material 4 may be provided by an interlock between the electrically conductive material 10 and the scallops 16 of the roughened sidewalls of the through-hole 12.

FIG. 5 schematically illustrates a cross-sectional side view of an adhesion promoting structure of a semiconductor device 500 in accordance with the disclosure. FIG. 5 may be seen as a more detailed illustration of corresponding components of FIGS. 1 and 2. The semiconductor device 500 may inter alia include an encapsulation material 4 and a recess 2 extending into the bottom surface of the encapsulation material 4. An electrically conductive material 10 may be deposited into the recess 2 and over the bottom surface of the encapsulation material 4 by applying a spraying technique. An adhesion promoting layer 18 may be arranged on the bottom of the recess 2. In addition, an electrically conductive structure 20, such as e.g. a conductor track, may be arranged over the upper surface of the encapsulation material 4. In the example of FIG. 5, an adhesion promoting structure 8 may be provided by the adhesion promoting layer 18 which e.g. may include or may be made of a soft metal, such as e.g. aluminum.

In FIG. 5 the adhesion promoting layer 18 may be separate from the electrically conductive structure 20. In a further example, the adhesion promoting structure 8 may be formed by the section of the electrically conductive structure 20 arranged over the recess 2. That is, the adhesion promoting layer 18 may be omitted, and the bottom of the recess 2 may be formed by the electrically conductive structure 20. In this further example, the depth of the recess 2 may be increased until the electrically conductive structure 20 arranged on the upper surface of the encapsulation material 4 may become exposed from the encapsulation material 4 so that the bottom of the recess 2 may be formed by the electrically conductive structure 20. That is, the electrically conductive structure 20 may act as e.g. a conductor track, and may additionally provide the functionality of an adhesion promoting structure 8 enhancing an adhesion between the encapsulation material 4 and the sprayed material 10. In such case, the sidewalls of the recess 2 may remain free from the adhesion promoting material.

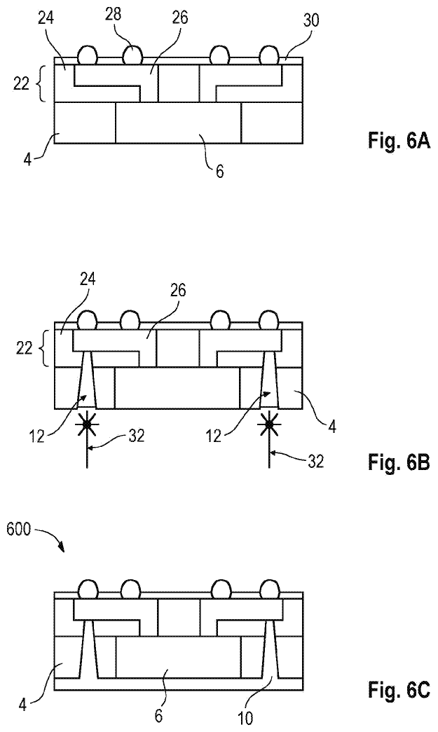

FIG. 6 includes FIGS. 6A to 6C schematically illustrating a cross-sectional side view of a method for manufacturing a semiconductor device 600 in accordance with the disclosure.

In FIG. 6A, an arrangement may be provided including a semiconductor chip 6 partly embedded in an encapsulation material 4. In a foregoing act (not illustrated), material of at least one of the encapsulation material 4 and the semiconductor chip 6 may be removed from the bottom surface (or backside) of the arrangement in order to expose the backside of the semiconductor chip 6 from the encapsulation material 4. For example, the material may be removed by applying at least one of grinding, chemical mechanical polishing, etching, etc. A redistribution layer 22 may be arranged over the upper surface (or the frontside) of the semiconductor chip 6. The redistribution layer 22 may include one or more dielectric layers 24 electrically insulating one or more metallization layers 26 embedded therein. The metallization layers 26 may be formed as conductor tracks configured to make electrical contacts of the semiconductor chip 6 available at other positions of the arrangement. For example, electrical contacts arranged on the upper surface of the semiconductor chip 6 may be electrically connected to external contact elements 28, such as e.g. solder balls, arranged on the upper surface of the arrangement. The arrangement may further include an electrically insulating layer 30 arranged over the redistribution layer 22.

In FIG. 6B, through-holes 12 may be formed in the encapsulation material 4 by e.g. applying a laser beam 32 in a laser drilling process. The laser drilling process may be stopped by or at the metallization layers 26. The through-holes 12 may thus fully extend through the encapsulation material 4 and at least partly through the dielectric layers 24, wherein at the bottom of the respective through-hole 12 the metallization layers 26 may be exposed from the encapsulation material 4.

In FIG. 6C, an electrically (and thermally) conductive material 10 may be sprayed into the through-holes 12 and over the bottom surfaces of the encapsulation material 4 and the semiconductor chip 6. An adhesion between the sprayed material 10 and the encapsulation material 4 may be provided by one or multiple adhesion promoting structures as e.g. discussed in connection with FIGS. 3 to 5. In a further optional act (not illustrated), a seed layer may be deposited over the bottom surfaces of the encapsulation material 4 and the semiconductor chip 6 before the spraying act, for example by applying at least one of sputtering and galvanic deposition. In this connection, it is to be noted that the semiconductor device 600 may include additional electrically insulating structures (not illustrated for the sake of simplicity) configured to prevent shorts between the components shown in FIG. 6.

The sprayed material 10 may be configured to cool the semiconductor device 600 at the bottom surface. In addition, heat may be dissipated from the upper surface to the bottom surface of the semiconductor device 600 via the filled through encapsulation vias. That is, the sprayed material 10 may provide a double sided cooling of the semiconductor device 600. In order to even more improve the cooling effect, the sprayed material 10 may additionally be connected to a heatsink (not illustrated) which may be arranged over the bottom surface of the semiconductor device 600.

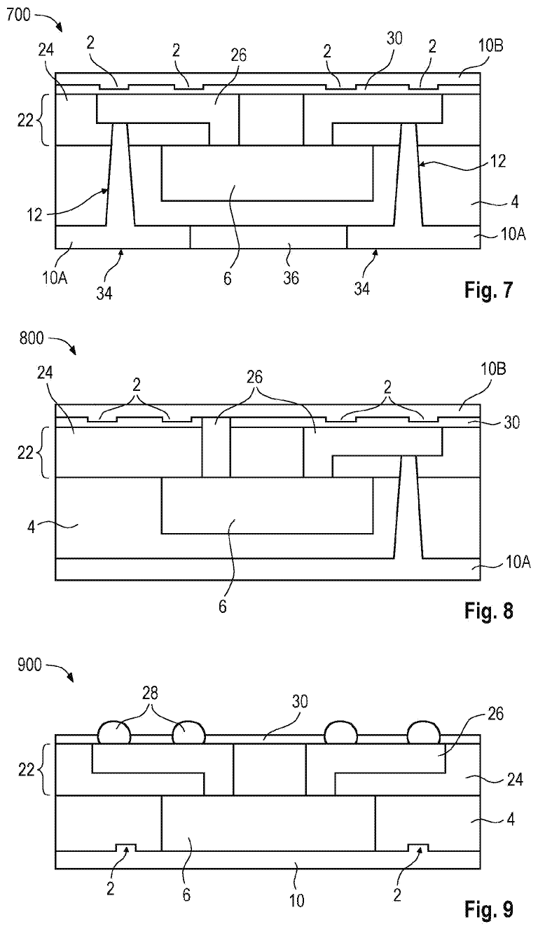

FIG. 7 schematically illustrates a cross-sectional side view of a semiconductor device 700 in accordance with the disclosure. The semiconductor device 700 may at least partly include similar components as shown in FIG. 6. A first sprayed electrically conductive material 10A may be arranged in through-holes 12 and on the bottom surface of the semiconductor device 700. An adhesion between the first sprayed material 10A and the encapsulation material 4 may be provided by an adhesion promoting structure as e.g. discussed in connection with FIGS. 3 to 5. In contrast to FIG. 6, the first sprayed material 10A may provide an electrical redistribution of electrical contacts arranged over the upper surface of the semiconductor chip 6 to the bottom surface of the semiconductor device 700 via the through encapsulation vias. For example, the first sprayed material 10A may form landing pads 34, i.e. contact pads configured to connect the semiconductor device 700 to a circuit board later on. The two exemplary landing pads 34 illustrated in FIG. 7 may be electrically insulated from each other by an electrically insulating material 36 in order to avoid shorts.

An electrically insulating layer 30, which may e.g. include or may be made of an imide, may be arranged over the redistribution layer 22. A second sprayed electrically (and thermally) conductive material 10B may be arranged over the electrically insulating layer 30. The electrically insulating layer 30 may include an arbitrary number of recesses 2 so that an adhesion between the second sprayed material 10B and the layer 30 may be provided by an adhesion promoting structure as e.g. discussed in connection with FIG. 1. The second sprayed material 10B may provide an insulated heat dissipation for cooling the semiconductor device 700 during operation.

FIG. 8 schematically illustrates a cross-sectional side view of a semiconductor device 800 in accordance with the disclosure. The semiconductor device 800 may at least partly include similar components as shown in FIGS. 6 and 7. In particular, the semiconductor device 800 may inter alia include two sprayed electrically conductive materials 10A and 10B. The first sprayed material 10A may provide an electrical redistribution of an electrical contact arranged over the upper surface of the semiconductor chip 6 to the bottom surface of the semiconductor device 800 via one or more through encapsulation vias. An adhesion between the first sprayed material 10A and the encapsulation material 4 may be provided by an adhesion promoting structure as e.g. discussed in connection with FIGS. 3 to 5.

The second sprayed material 10B may provide an electrical redistribution of an electrical contact arranged over the upper surface of the semiconductor chip 6 to the upper surface of the semiconductor device 800. In particular, the second sprayed material 10B may form a layer electrically coupled to a via connection of the redistribution layer 22. An adhesion between the second sprayed material 10B and the electrically insulating material 30 may e.g. be provided by adhesion promoting structures arranged in recesses 2.

FIG. 9 schematically illustrates a cross-sectional side view of a semiconductor device 900 in accordance with the disclosure. The semiconductor device 900 may at least partly include similar components as shown in FIGS. 6 to 8. In particular, the semiconductor device 900 may inter alia include a sprayed electrically conductive material 10 arranged over bottom surfaces of the encapsulation material 4 and the semiconductor chip 6. An adhesion between the sprayed material 10 and the encapsulation material 4 may be provided by adhesion promoting structures arranged in recesses 2. In one example, the semiconductor device 900 may optionally include a diffusion barrier layer (not illustrated) arranged between the encapsulation material 4 and the sprayed material 10. For example, the diffusion barrier layer may include or may be made of TiW. The sprayed material 10 may form a heatsink configured to provide a heat dissipation and a cooling of the semiconductor device 900. That is, the sprayed material 10 may at least partly provide functionalities of a leadframe. Accordingly, compared to conventional semiconductor devices, the arrangement of FIG. 9 is not required to include a leadframe.

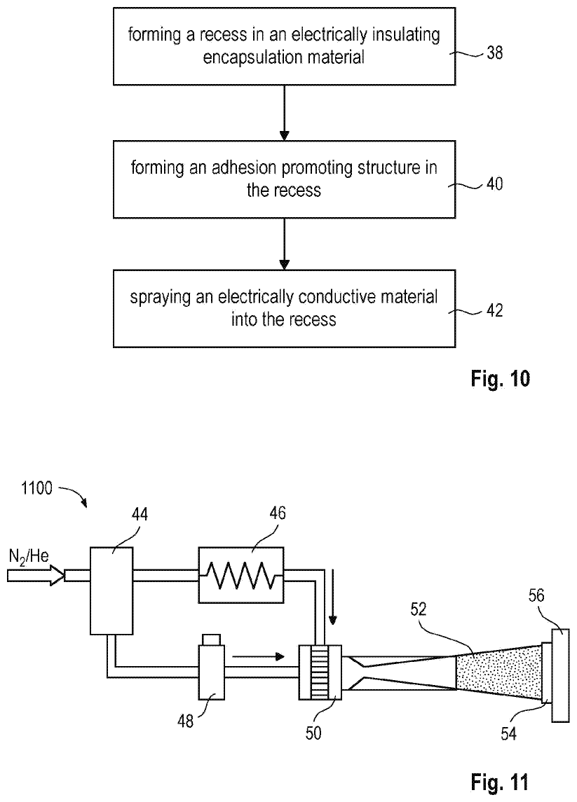

FIG. 10 illustrates a flowchart of a method for manufacturing a semiconductor device in accordance with the disclosure. The method may be similar to and may be read in connection with the method of FIG. 1.

At 38, a recess is formed in an electrically insulating encapsulation material, wherein the encapsulation material at least partly encapsulates a semiconductor chip. At 40, an adhesion promoting structure is formed in the recess. At 42, an electrically conductive material is sprayed into the recess, wherein the adhesion promoting structure is configured to provide an adhesion between the sprayed material and the encapsulation material.

FIG. 11 schematically illustrates an arrangement 1100 for applying a cold gas spraying technique. The arrangement 1100 may include a gas control module 44, an electric heater 46, a powder feeder 48, and a supersonic nozzle 50. A working gas, such as e.g. N₂ or He, may enter the arrangement 1100 at an inlet. In an upper processing path, the gas control module 44 may forward controlled amounts of the working gas to the electric heater 46 where the gas may be heated. The heated working gas stream may then be forwarded to the supersonic nozzle 50. In a lower processing path, the powder feeder 48 may provide solid powder particles of a deposition material to the supersonic nozzle 50. For example, the powder particles may have a diameter from about 1 micrometer to about 50 micrometer. The powder particles may be inserted at high pressure at the nozzle entrance and may be accelerated in a supersonic gas jet to velocities up to from about 500 m/s to about 1000 m/s. A gas stream 52 including the powder particles exiting the supersonic nozzle 50 may have a temperature in a range from about 100° C. to about 500° C. The particle stream 52 may hit a target 54 which may be arranged on a substrate 56.

Plasma dust spraying techniques may be similar to cold gas spraying techniques. In plasma dust spraying the material to be deposited may not be accelerated by means of a supersonic gas jet, but may receive the required kinetic energy for an acceleration from a high-temperature plasma. In a similar fashion, the accelerated deposition material may be provided by a “plasma nozzle”.

FIG. 12 schematically illustrates a supersonic nozzle 1200 providing a gas stream including particles 58 to be deposited on a target 54. During impact with the target 54, the particles 58 may undergo plastic deformation and may adhere to a surface of the target 54. In general, metals, polymers, ceramics, composite materials, and nanocrystalline powders may be deposited using cold gas spraying. The powders used in cold gas spraying may not necessarily be melted during the spraying process. In particular, the surface of a material deposited by a cold gas spraying technique may have a dented surface structure as exemplarily shown in the cross-sectional side view of FIG. 12.

FIG. 13 is a stress-temperature diagram illustrating a temperature-dependency of stress that may occur in cooper layers manufactured by different deposition methods. The horizontal axis of the diagram shows the temperature in units of ° C. while the vertical axis of the diagram shows the stress in units of MPa. A positive value of the stress may relate to a warpage of the deposited material occurring in a first direction while a negative value of the stress may relate to a warpage occurring in an opposite second direction. The solid line refers to a copper layer deposited by a physical vapor deposition (PVD) technique. The dashed line refers to a copper layer deposited by an electro chemical deposition (ECD) technique. The dotted line refers to a copper layer deposited by a plasma dust (PD) spraying technique.

The lower part of each graph basically shows that the occurring stress is reduced when the temperature is increased (see “heating”). The upper part of each graph basically shows that the occurring stress is increased when the temperature is lowered (see “cooling”). When comparing the three graphs of FIG. 13, it can be seen that, in overall terms, stress occurring in a deposited copper layer may be reduced when choosing a plasma dust spraying technique for depositing the copper layer.

In addition to the mechanical properties discussed in connection with FIG. 13, metal or metal alloys deposited by applying a cold gas spraying technique may have the following properties. The values discussed in the following may particularly relate to cold gas sprayed copper.

An electrical resistivity of a cold sprayed metal or metal alloy may lie in a range from about 6μΩ·cm to about 150μΩ·cm as deposited, i.e. directly after the deposition. After applying a forming gas (FG) annealing technique, the electrical resistivity may lie in a range from about 3μΩ·cm to about 15μΩ·cm. Here, the electrical resistivity of the annealed cold sprayed metal may be 1.5 times the electrical resistivity of a corresponding bulk material. In particular, values below 5μΩ·cm may be obtained by applying an FG annealing at a temperature of about 400° C. In one specific example, a plasma dust sprayed copper layer with a thickness of about 100 micrometer shows an electrical resistivity of about 10μΩ·cm after an annealing process at a temperature of about 240° C.

A thickness of a cold sprayed metal or metal alloy layer may lie in a range from about 15 micrometer to about 450 micrometer. In particular, the thickness may be greater than about 100 micrometer, more particular greater than about 200 micrometer, more particular greater than about 300 micrometer, and even more particular greater than about 400 micrometer.

A stress occurring in a cold sprayed metal or metal alloy layer may lie in a range from about 10 MPa to about 150 MPa.

An adhesion of a cold sprayed metal or metal alloy material as deposited, i.e. directly after the deposition, may be greater than about 600 kg/cm², in particular at a deposition temperature of greater than about 180° C. After applying an FG annealing technique, the adhesion of the annealed cold gas sprayed material may be greater than about 600 kg/cm², in particular at an annealing temperature greater than about 400° C. In one specific example, copper cold gas sprayed to copper, silicon, silicon oxide, mold compound, and solder resist passed several adhesion tests. Note that the adhesion of the material may depend on a used seed layer. A seed layer including or made of copper or silver or aluminum may be suitable for providing good adhesion values. A seed layer including or made of gold may be suitable for providing even better and very good adhesion values.

### EXAMPLES

In the following, semiconductor devices including adhesion promoting structures and methods for manufacturing thereof will be explained by means of examples.

Example 1 is a method, comprising: forming a recess in an electrically insulating encapsulation material, wherein the encapsulation material at least partly encapsulates a semiconductor chip; forming an adhesion promoting structure in the recess; and spraying an electrically conductive material into the recess, wherein the adhesion promoting structure is configured to provide an adhesion between the sprayed electrically conductive material and the encapsulation material.

Example 2 is a method according to Example 1, wherein spraying the electrically conductive material comprises at least one of cold gas spraying and plasma dust spraying the electrically conductive material.

Example 3 is a method according to Example 1 or 2, wherein the sprayed electrically conductive material comprises at least one of copper, aluminum, iron, nickel, alloys thereof, bronze, brass.

Example 4 is a method according to one of the preceding Examples, wherein forming the recess comprises applying at least one of an etching process and a laser process to the encapsulation material, and forming the adhesion promoting structure comprises roughening a sidewall of the recess by the at least one of the etching process and the laser process.

Example 5 is a method according to Example 4, wherein roughening the sidewall comprises forming at least one of scallops and undercuts on the sidewall.

Example 6 is a method according to Example 4 or 5, wherein the encapsulation material comprises at least one of filler particles and filler fibers, and roughening the sidewall comprises breaking the at least one of the filler particles and the filler fibers out of the encapsulation material during the at least one of the etching process and the laser process.

Example 7 is a method according to one of the preceding Examples, wherein forming the recess comprises forming a via hole, wherein the via hole extends through the encapsulation material from a first surface of the encapsulation material to a second surface of the encapsulation material.

Example 8 is a method according to Example 7, wherein spraying the electrically conductive material comprises forming an electrical via connection through the encapsulation material, wherein the electrical via connection is electrically coupled to the semiconductor chip.

Example 9 is a method according to one of the preceding Examples, wherein forming the adhesion promoting structure comprises forming an adhesion promoting layer in the recess.

Example 10 is a method according to Example 9, wherein forming the adhesion promoting layer comprises forming the recess in a first surface of the encapsulation material until an electrically conductive structure, in particular a conductor track, arranged on a second surface of the encapsulation material is exposed from the encapsulation material at the bottom of the recess.

Example 11 is a method according to Example 9 or 10, wherein, after spraying the electrically conductive material, sidewalls of the recess are uncovered by the adhesion promoting layer.

Example 12 is a method according to one of Examples 9 to 11, wherein the adhesion promoting layer comprises a soft metal, in particular aluminum.

Example 13 is a method according to one of the preceding Examples, further comprising spraying the electrically conductive material over at least one of a surface of the encapsulation material and a surface of the semiconductor chip.

Example 14 is a semiconductor device, comprising: a semiconductor chip; an electrically insulating encapsulation material at least partly encapsulating the semiconductor chip; a recess arranged in the encapsulation material; a sprayed electrically conductive material arranged in the recess; and an adhesion promoting structure arranged in the recess and configured to provide an adhesion between the sprayed electrically conductive material and the encapsulation material.

Example 15 is a semiconductor device according to Example 14, wherein the adhesion promoting structure comprises at least one of scallops and undercuts formed on a sidewall of the recess, wherein the sprayed electrically conductive material and the sidewall are interlocked by the at least one of the scallops and the undercuts.

Example 16 is a semiconductor device according to Example 14 or 15, wherein the recess is arranged in a first surface of the encapsulation material, an electrically conductive structure is arranged on a second surface of the encapsulation material, the electrically conductive structure forms a bottom of the recess, and the adhesion promoting structure comprises the electrically conductive structure.

Example 17 is a semiconductor device according to one of Examples 14 to 16, wherein a porosity of the sprayed electrically conductive material lies in a range from 10% to 50%.

Example 18 is a semiconductor device according to one of Examples 14 to 17, wherein the encapsulation material comprises at least one of filler particles and filler fibers.

Example 19 is a semiconductor device according to one of Examples 14 to 18, wherein the sprayed electrically conductive material forms an electrical via connection between a first surface and a second surface of the encapsulation material.

Example 20 is a semiconductor device according to one of Examples 14 to 19, wherein the sprayed electrically conductive material is further arranged over at least one of a surface of the encapsulation material and a surface of the semiconductor chip, and the sprayed electrically conductive material forms at least one of a conductor track and a heatsink.

Example 21 is a semiconductor device according to one of Examples 14 to 20, wherein the sprayed electrically conductive material is further arranged over at least one of a surface of the encapsulation material and a surface of the semiconductor chip, and the sprayed electrically conductive material forms a shielding. The shielding may be configured to protect an application and/or one or more parts of the semiconductor device against at least one of radiation and material diffusion. In one example, the shielding may be configured to protect an HF (high frequency) application against radiation. In a further example, the shielding may be configured to protect a sensor application against material diffusion, such as e g humidity diffusion and/or gas diffusion.

As employed in this description, the terms “connected”, “coupled”, “electrically connected” and/or “electrically coupled” may not necessarily mean that elements must be directly connected or coupled together. Intervening elements may be provided between the “connected”, “coupled”, “electrically connected” or “electrically coupled” elements.

Further, the word “over” used with regard to e.g. a material layer formed or located “over” a surface of an object may be used herein to mean that the material layer may be located (e.g. formed, deposited, etc.) “directly on”, e.g. in direct contact with, the implied surface. The word “over” used with regard to e.g. a material layer formed or located “over” a surface may also be used herein to mean that the material layer may be located (e.g. formed, deposited, etc.) “indirectly on” the implied surface with e.g. one or more additional layers being arranged between the implied surface and the material layer.

Furthermore, to the extent that the terms “having”, “containing”, “including”, “with” or variants thereof are used in either the detailed description or the claims, such terms are intended to be inclusive in a manner similar to the term “comprising”. That is, as used herein, the terms “having”, “containing”, “including”, “with”, “comprising” and the like are open-ended terms that indicate the presence of stated elements or features, but do not preclude additional elements or features.

Moreover, the word “exemplary” is used herein to mean serving as an example, instance, or illustration. Any aspect or design described herein as “exemplary” is not necessarily to be construed as advantageous over other aspects or designs. Rather, use of the word exemplary is intended to present concepts in a concrete fashion.

Devices and methods for manufacturing devices are described herein. Comments made in connection with a described device may also hold true for a corresponding method and vice versa. For example, if a specific component of a device is described, a corresponding method for manufacturing the device may include an act of providing the component in a suitable manner, even if such act is not explicitly described or illustrated in the figures.

While this disclosure has been described with reference to illustrative embodiments, this description is not intended to be construed in a limiting sense. Various modifications and combinations of the illustrative embodiments, as well as other embodiments of the disclosure, will be apparent to persons skilled in the art upon reference to the description. It is therefore intended that the appended claims encompass any such modifications or embodiments.

1. A method, comprising:
forming a recess in an electrically insulating encapsulation material, wherein the encapsulation material at least partly encapsulates a semiconductor chip;
forming an adhesion promoting structure in the recess; and
spraying an electrically conductive material into the recess, wherein the adhesion promoting structure is configured to provide an adhesion between the sprayed electrically conductive material and the encapsulation material.

2. The method of claim 1, wherein spraying the electrically conductive material comprises at least one of cold gas spraying and plasma dust spraying the electrically conductive material.

3. The method of claim 1, wherein the sprayed electrically conductive material comprises at least one of copper, aluminum, iron, nickel, alloys thereof, bronze, brass.

4. The method of claim 1, wherein
forming the recess comprises applying at least one of an etching process and a laser process to the encapsulation material, and
forming the adhesion promoting structure comprises roughening a sidewall of the recess by the at least one of the etching process and the laser process.

5. The method of claim 4, wherein roughening the sidewall comprises forming at least one of scallops and undercuts on the sidewall.

6. The method of claim 4, wherein
the encapsulation material comprises at least one of filler particles and filler fibers, and
roughening the sidewall comprises breaking the at least one of the filler particles and the filler fibers out of the encapsulation material during the at least one of the etching process and the laser process.

7. The method of claim 1, wherein forming the recess comprises forming a via hole, wherein the via hole extends through the encapsulation material from a first surface of the encapsulation material to a second surface of the encapsulation material.

8. The method of claim 7, wherein spraying the electrically conductive material comprises forming an electrical via connection through the encapsulation material, wherein the electrical via connection is electrically coupled to the semiconductor chip.

9. The method of claim 1, wherein forming the adhesion promoting structure comprises forming an adhesion promoting layer in the recess.

10. The method of claim 9, wherein forming the adhesion promoting layer comprises forming the recess in a first surface of the encapsulation material until an electrically conductive structure, in particular a conductor track, arranged on a second surface of the encapsulation material is exposed from the encapsulation material at the bottom of the recess.

11. The method of claim 9, wherein, after spraying the electrically conductive material, sidewalls of the recess are uncovered by the adhesion promoting layer.

12. The method of claim 9, wherein the adhesion promoting layer comprises a soft metal, in particular aluminum.

13. The method of claim 1, further comprising spraying the electrically conductive material over at least one of a surface of the encapsulation material and a surface of the semiconductor chip.

14. A semiconductor device, comprising:
a semiconductor chip;
an electrically insulating encapsulation material at least partly encapsulating the semiconductor chip;
a recess arranged in the encapsulation material;
a sprayed electrically conductive material arranged in the recess; and
an adhesion promoting structure arranged in the recess and configured to provide an adhesion between the sprayed electrically conductive material and the encapsulation material.

15. The semiconductor device of claim 14, wherein the adhesion promoting structure comprises at least one of scallops and undercuts formed on a sidewall of the recess, wherein the sprayed electrically conductive material and the sidewall are interlocked by the at least one of the scallops and the undercuts.

16. The semiconductor device of claim 14, wherein
the recess is arranged in a first surface of the encapsulation material,
an electrically conductive structure is arranged on a second surface of the encapsulation material,
the electrically conductive structure forms a bottom of the recess, and
the adhesion promoting structure comprises the electrically conductive structure.

17. The semiconductor device of claim 14, wherein a porosity of the sprayed electrically conductive material lies in a range from 10% to 50%.

18. The semiconductor device of claim 14, wherein the encapsulation material comprises at least one of filler particles and filler fibers.

19. The semiconductor device of claim 14, wherein the sprayed electrically conductive material forms an electrical via connection between a first surface and a second surface of the encapsulation material.

20. The semiconductor device of claim 14, wherein
the sprayed electrically conductive material is further arranged over at least one of a surface of the encapsulation material and a surface of the semiconductor chip, and
the sprayed electrically conductive material forms at least one of a conductor track and a heatsink.
